(19) United States
(12) Patent Application Publication
(10) Pub. No.: US 2017/0043553 A1
(43) Pub. Date: Feb. 16, 2017

(54) HEAT-STORAGE, THERMALLY CONDUCTIVE SHEET

(71) Applicant: Fuji Polymer Industries Co., Ltd., Nagoya, Aichi (JP)

(72) Inventor: Jinya TANAKA, Aichi (JP)

(21) Appl. No.: 15/304,413

(22) PCT Filed: Dec. 18, 2015
(86) PCT No.: PCT/JP2015/085495

§ 371 Date: Oct. 14, 2016

(30) Foreign Application Priority Data
Jan. 6, 2015 (JP) 2015-001179

(51) Int. Cl. B32B 5/16; H01L 23/373; B32B 15/04; B32B 7/02; B32B 9/00

(52) U.S. Cl. CPC B32B 5/16; B32B 7/02; B32B 9/007; B32B 15/04; H01L 23/3737; H01L 23/3735; B32B 2307/302

(57) ABSTRACT

A heat storage and conduction sheet (3, 4, 5) of the present invention includes: a heat storage sheet (1, 1a, 1b) including a matrix resin and heat storage inorganic particles; and a heat diffusing material (2, 2a, 2b) that is united with the heat storage sheet. The heat storage inorganic particles are composed of a material that undergoes an electronic phase transition and has a latent heat of 1 J/cc or more for the electronic phase transition. The amount of the heat storage inorganic particles is 10 to 2000 parts by mass with respect to 100 parts by mass of the matrix resin. The heat storage sheet has a heat conductivity of 0.3 W/m·K or more. The heat diffusing material has a heat conductivity in a planar direction of 20 to 2000 W/m·K. Thus, the present invention provides a physically stable heat storage and conduction sheet having high heat storage properties and high heat conduction properties, and excellent heat diffusion properties in a planar direction.

### TECHNICAL FIELD

The present invention relates to a heat storage and conduction sheet. More specifically, the present invention relates to a heat storage and conduction sheet having excellent heat diffusion properties in a planar direction.

### BACKGROUND ART

A semiconductor used in electronic equipment or the like generates heat during operation, and the performance of electronic components may be deteriorated by the heat. Therefore, a metallic heat dissipating member is generally attached to a heat generating electronic component via a heat conductive sheet in the form of gel or soft rubber. In recent years, however, another method has been proposed in which a heat storage material sheet is attached to a heat generating electronic component so that heat is stored in the heat storage material sheet, and thus a heat transfer rate is reduced. Patent Documents 1 to 2 propose heat storage rubber that incorporates microcapsules containing a heat storage material. Patent Document 3 proposes a member for countermeasures against heat. The member is obtained by coating the entire surface of a silicone elastomer with a coating material. The silicon elastomer includes a paraffin wax polymer and a heat conductive filler. Patent Document 4 proposes, e.g., a vanadium oxide containing trace metal such as tungsten as a heat storage material.

### PRIOR ART DOCUMENTS

### Patent Documents

Patent Document 1: JP 2010-184981 A

Patent Document 2: JP 2010-235709 A

Patent Document 3: JP 2012-102264 A

Patent Document 4: JP 2010-163510 A

### DISCLOSURE OF INVENTION

### Problem to be Solved by the Invention

However, the approaches in Patent Documents 1 to 2 have the problem that heat is not easily transferred from the heat generating member to the heat storage material, since the gel or soft rubber itself is a heat insulating material. The approaches in Patent Documents 3 to 4 also have the problem that both heat storage properties and heat conduction properties need to be improved further. Moreover, the microcapsules are likely to be broken when they are mixed with a matrix resin material. Patent Documents 1 to 3 utilize latent heat associated with a change in the state of the material (such as paraffin) from liquid to solid or solid to liquid. However, the material in the liquid state is dissolved in a matrix phase and cannot provide the heat storage effect, or the heat storage performance is reduced, upon repeated use. To deal with this issue, it has been proposed that a material having the heat storage effect is microencapsulated. However, some of the microcapsules are likely to be broken when they are mixed with a matrix material, and thus the microencapsulation is not sufficient to suppress a reduction in the heat storage performance due to the repeated use. In the member for countermeasures against heat of Patent Document 3, the entire surface of the silicone elastomer that includes the paraffin wax polymer and the heat conductive filler is coated with the coating material in order to prevent leaching of the paraffin wax (heat storage material). However, Patent Document 3 cannot solve the fundamental problem of a reduction in the heat storage performance due to the repeated use. Patent Document 4 teaches that an electronic phase transition rather than the latent heat of a liquid-solid phase change contributes to the heat storage effect. However, Patent Document 4 does not refer to the possibility or expected effect of using a material that undergoes an electronic phase transition in combination with a polymer matrix. Moreover, the use of the material that undergoes an electronic phase transition with a thermosetting polymer may inhibit the curing of the polymer. Moreover, the approaches in Patent Documents 1 to 4 also have the problem that heat diffusion properties in a planar direction are poor.

To solve the above conventional problems, the present invention provides a physically stable heat storage and conduction sheet having high heat storage properties and high heat conduction properties, and excellent heat diffusion properties in a planar direction.

### Means for Solving Problem

The heat storage and conduction sheet of the present invention includes: a heat storage sheet that includes a matrix resin and heat storage inorganic particles; and a heat diffusing material that is united with the heat storage sheet. The heat storage inorganic particles are composed of a material that undergoes an electronic phase transition and has a latent heat of 1 J/cc or more for the electronic phase transition. The amount of the heat storage inorganic particles is 1.0 to 2000 parts by mass with respect to 100 parts by mass of the matrix resin. The heat storage sheet has a heat conductivity of 0.3 W/m·K or more. The heat diffusing material has a heat conductivity in a planar direction of 20 to 2000 W/m·K.

### Effect of the Invention

By laminating a heat diffusing material on any part of a heat storage sheet that includes a matrix resin and heat storage inorganic particles, the present invention can provide a physically stable heat storage and conduction sheet having high heat storage properties and high heat conduction properties, and excellent heat diffusion properties in a planar direction. Specifically, with this configuration, heat from a heat generating component is transferred and stored in the heat storage sheet so that the heat conduction is delayed, and the heat is diffused during the delay and transferred to the heat diffusing material to be diffused in a planar direction, whereby partial heating or a hot spot is eliminated or reduced and uniform heat dissipation becomes possible. A heat diffusion effect obtained by both of the heat storage sheet and the heat diffusing material allows heat from the heat generating component to be diffused and dissipated. Further, since the materials that exhibit heat storage properties and heat conduction properties are both inorganic substances, a stable heat storage and conduction sheet can be obtained even when they are mixed with a matrix resin material. Moreover, by laminating the heat diffusing material on the heat storage sheet, heat resistance at an interface therebetween is reduced, whereby heat diffusion properties in a planar direction can be enhanced.

### BRIEF DESCRIPTION OF DRAWINGS

FIGS. 1A to 1C are schematic cross-sectional views of heat storage and conduction sheets in an example of the present invention.

FIG. 2A is a schematic cross-sectional view of a heat diffusion measuring apparatus in an example of the present invention, and FIG. 2B is a plan view showing the measurement points of the temperature of a heat storage and conduction sheet in an example of the present invention.

FIGS. 3A and 3B are diagrams illustrating a method for measuring a heat conductivity and a heat resistance value of a heat storage and conduction sheet in an example of the present invention.

FIG. 4 is a graph showing an increase in the temperature of a sheet in Example 1 of the present invention.

FIG. 5 is a graph showing an increase in the temperature of a sheet in Comparative Example 1.

FIG. 6 is a graph showing an increase in the temperature of a sheet in Example 2 of the present invention.

FIG. 7 is a graph showing an increase in the temperature of a sheet in Comparative Example 2.

FIG. 8 is a graph showing an increase in the temperature of a sheet in Example 3 of the present invention.

FIG. 9 is a graph showing an increase in the temperature of a sheet in Example 4 of the present invention.

FIG. 10 is a graph showing an increase in the temperature of a sheet in Example 5 of the present invention.

### DESCRIPTION OF THE INVENTION

A heat storage and conduction sheet of the present invention is a sheet obtained by laminating a heat diffusing material on any part of a heat storage sheet. For example, a heat diffusing material may be placed on one or both principal surfaces of a heat storage sheet, and/or may be placed in an inner layer of heat storage sheets for integration. As an example, a heat storage sheet and a heat diffusing material are laminated by subjecting one or both laminating surfaces of the heat storage sheet and the heat diffusing material to a corona treatment. By the corona treatment, the laminating surfaces are activated, and the heat storage sheet and the heat diffusing material are united strongly. Further, since the heat storage sheet and the heat diffusing material are united by direct bonding, heat resistance at the interface is low, and a heat storage and conduction sheet with excellent heat conduction properties can be obtained. A heat storage sheet having surface tackiness can be directly bonded with a heat diffusing material by only its tack force.

The heat diffusing material is preferably a graphite sheet, or a metal or alloy selected from gold, platinum, silver, titanium, aluminum, palladium, copper, and nickel. These heat diffusing materials have high heat diffusion properties, in particular, they can increase heat diffusion properties in a planar direction. Among these materials, a graphite sheet having high heat diffusion properties in a planar direction is preferred. When the heat storage and conduction sheet of the present invention is interposed between a heat generating member and a heat dissipating member, heat generated from the heat generating member is first transferred to the heat storage sheet, and thereafter transferred to the heat diffusing material to be diffused in a planar direction.

As the graphite sheet, a laminated graphite sheet or a graphite sheet sandwiched by polyethylene terephthalate (PET) films so as to avoid dropping of graphite can be used directly. A mesh graphite sheet also can be used similarly.

The heat storage sheet of the present invention is made from a heat storage composition that includes a matrix resin and heat storage inorganic particles, and produced by forming the composition into a sheet. The heat storage inorganic particles are composed of a material that undergoes an electronic phase transition and has a latent heat of 1 J/cc or more for the electronic phase transition. The latent heat is preferably 1 to 500 J/cc, more preferably 140 to 240 J/cc. The latent heat is synonymous with transition enthalpy. The heat storage inorganic particles are preferably metal oxide particles containing vanadium as a main metal component. The amount of the heat storage inorganic particles is 10 to 2000 parts by mass with respect to 100 parts by mass of the matrix resin. The heat storage composition has a heat conductivity of 0.3 W/m·K or more. The metal oxide particles containing vanadium as a main metal component are excellent in both heat storage properties and heat conductivity and advantageous in that heat from the outside is absorbed and stored in the heat storage composition even if the matrix resin is a heat-insulating resin. Further, the heat storage composition having the above heat conductivity can absorb heat from the outside easily.

The heat storage inorganic particles, which are composed of a material that undergoes an electronic phase transition and has a latent heat of 1 J/cc or more for the electronic phase transition, are preferably VO₂, LiMn₂O₄, LiVS₂, LiVO₂, NaNiO₂, LiRh₂O₄, V₂O₃, V₄O₇, V₆O₁₁, Ti₄O₇, SmBaFe₂O₅, EuBaFe₂O₅, GdBaFe₂O₅, TbBaFe₂O₅, DyBaFe₂O₅, HoBaFe₂O₅, YBaFe₂O₅, PrBaCo₂O_{5.5}, DyBaCo₂O_{5.54}, HoBaCo₂O_{5.48}, YBaCo₂O_{5.49}, or the like. The temperature of electronic phase transition of these compounds and the latent heat for the electronic phase transition thereof are shown in FIG. 7 of Patent Document 4. Among these, VO₂ is preferred from the viewpoint of heat storage properties and heat conductivity. An element Q such as Al, Ti, Cr, Mn, Fe, Cu, Ga, Ge, Zr, Nb, Mo, Ru, Sn, Hf, Ta, W, Re, Os, or Ir may be dissolved in vanadium oxide to form a solid solution. It is preferred that VO₂ containing the element Q is expressed by V₍₁₋ₓ₎QₓO₂(where 0≦x<1).

The average particle size of the vanadium oxide particles is preferably 0.1 to 100 μm, more preferably 1 to 50 μm. Within this range, the particles can favorably be mixed and processed with the matrix resin. The particle size may be measured with a laser diffraction scattering method to determine a particle size at 50% (by mass). The method may use a laser diffraction particle size analyzer LA-950S2 manufactured by Horiba, Ltd.

The heat storage inorganic particles of the present invention can be either used as they are or surface treated with alkoxysilane or alkyl titanate. In the surface treatment, alkoxysilane or alkyl titanate is brought into contact with the surface of the heat storage inorganic particles and held by adsorption or a chemical bond, which makes the particles chemically stable. The alkoxysilane is preferably a silane compound or its partial hydrolysate. The silane compound is expressed by R(CH₃)ₐSi(OR′)₃₋ₐ, where R represents an alkyl group having 1 to 20 carbon atoms, R′ represents an alkyl group having 1 to 4 carbon atoms, and a is 0 or 1. Specifically, the alkoxysilane is the same as a surface treatment agent for heat conductive inorganic particles, as will be described later. The treatment conditions are also the same. The alkyl titanate is preferably tetrabutyl titanate. When the surface-treated heat storage inorganic particles are used with a thermosetting polymer, the curing of the polymer is not inhibited, so that a stable heat storage composition can be obtained. If the heat storage inorganic particles are not surface treated, the curing of the polymer may be inhibited. Thus, the previous surface treatment of the heat storage inorganic particles can prevent the curing of the polymer from being inhibited.

The matrix resin may be either a thermosetting resin or a thermoplastic resin The matrix resin may also include rubber and an elastomer. Examples of the thermosetting resin include (but are not limited to) the following: epoxy resin; phenol resin; unsaturated polyester resin; and melamine resin. Examples of the thermoplastic resin include (but are not limited to) the following: polyolefin such as polyethylene or polypropylene; polyester; nylon; ABS resin; methacrylate resin; polyphenylene sulfide; fluorocarbon resin; polysulfone; polyetherimide; polyethersulfone; polyetherketone; liquid crystalline polyester; polyimide; and copolymers, polymer alloys, or blended materials of them. A mixture of two or more types of thermoplastic resins may also be used. Examples of the rubber include (but are not limited to) the following: natural rubber (NR: ASTM abbreviaion); isoprene rubber (IR); butadiene rubber (BR); 1,2-polybutadiene rubber (1,2-BR); styrene-butadiene rubber (SBR); chloroprene rubber (CR); nitrile rubber (NBR); butyl rubber (IIR); ethylene-propylene rubber (EPM, EPDM); chlorosulfonated polyethylene (CSM); acrylic rubber (ACM, ANM); epichlorohydrin rubber (CO, ECO); polysulfide rubber (T); silicone rubber; fluorocarbon rubber (FKM); and urethane rubber (U). These materials can also be applied to the thermoplastic elastomer (TPE). Examples of the thermoplastic elastomer (TPE) include (but are not limited to) the following: styrene based TPE; olefin based TPE; vinyl chloride based TPE; urethane based TPE; ester based TPE; amide based TPE; chlorinated polyethylene based TPE; syn-1,2-polybutadiene based TPE; trans-1,4-polyisoprene based TPE; and fluorine based TPE. The matrix resin is preferably an organopolysiloxane. This is because the organopolysiloxane has high heat resistance and good processability. The heat storage composition including the organopolysiloxane as a matrix may be in any form of rubber, rubber sheet, putty, or grease.

When the organopolysiloxane is used as a matrix resin, a compound with the following composition may be obtained by crosslinking.

(A) Base polymer component: a linear organopolysiloxane having an average of two or more alkenyl groups per molecule, in which the alkenyl groups are bonded to silicon atoms at both ends of the molecular chain.

(B) Crosslinking component: an organohydrogenpolysiloxane having an average of two or more hydrogen atoms bonded to silicon atoms per molecule, in which the amount of the organohydrogenpolysiloxane is less than 1 mol with respect to 1 mol of the alkenyl groups bonded to the silicon atoms in the component (A).

(C) Platinum-based metal catalyst: the amount of the catalyst is 0.01 to 1000 ppm in mass with respect to the component (A).

(D) Heat storage inorganic particles (metal oxide particles containing vanadium as the main metal component): the amount of the heat storage inorganic particles is 10 to 2000 parts by mass with respect to 100 parts by mass of the matrix resin.

(E) Heat conductive particles (if added): the amount of the heat conductive particles is 100 to 2000 parts by mass with respect to 100 parts by mass of the matrix resin.

(F) Inorganic pigment: the amount of the inorganic pigment is 0.1 to 10 parts by mass with respect to 100 parts by mass of the matrix resin.

(1) Base Polymer Component

The base polymer component (component (A)) is an organopolysiloxane having two or more alkenyl groups bonded to silicon atoms per molecule. The organopolysiloxane containing two alkenyl groups is the base resin (base polymer component) of the silicone rubber composition of the present invention. In the organopolysiloxane, two alkenyl groups having 2 to 8 carbon atoms, and preferably 2 to 6 carbon atoms such as vinyl groups or allyl groups are bonded to the silicon atoms per molecule. The viscosity of the organopolysiloxane is preferably 10 to 1000000 mPa·s, and more preferably 100 to 100000 mPa·s at 25° C. in terms of workability and curability. Specifically, an organopolysiloxane expressed by the following general formula (chemical formula 1) is used. The organopolysiloxane has an average of two or more alkenyl groups per molecule, in which the alkenyl groups are bonded to silicon atoms at both ends of the molecular chain. The organopolysiloxane is a linear organopolysiloxane whose side chains are blocked with triorganosiloxy groups. The viscosity of the linear organopolysiloxane is preferably 10 to 1000000 mPa·s at 25° C. in terms of workability and curability. Moreover, the linear organopolysiloxane may include a small amount of branched structure (trifunctional siloxane units) in the molecular chain.

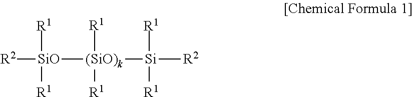

In this formula, R¹ represents substituted or unsubstituted monovalent hydrocarbon groups that are the same as or different from each other and have no aliphatic unsaturated bond, R² represents alkenyl groups, and k represents 0 or a positive integer. The monovalent hydrocarbon groups represented by R¹ preferably have 1 to 10 carbon atoms, and more preferably 1 to 6 carbon atoms. Specific examples of the monovalent hydrocarbon groups include the following: alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups. The alkenyl groups represented by R² preferably have 2 to 6 carbon atoms, and more preferably 2 to 3 carbon atoms. Specific examples of the alkenyl groups include vinyl, allyl, propenyl, isopropenyl, butenyl, isobutenyl, hexenyl, and cyclohexenyl groups. In particular, the vinyl group is preferred. In the general formula (1), k is typically 0 or a positive integer satisfying 0≦k≦10000, preferably 5≦k≦2000, and more preferably 10≦k≦1200.

The component (A) may also include an organopolysiloxane having three or more, typically 3 to 30, and preferably about 3 to 20, alkenyl groups bonded to silicon atoms per molecule. The alkenyl groups have 2 to 8 carbon atoms, and preferably 2 to 6 carbon atoms and can be, e.g., vinyl groups or allyl groups. The molecular structure may be a linear, ring, branched, or three-dimensional network structure. The organopolysiloxane is preferably a linear organopolysiloxane in which the main chain is composed of repeating diorganosiloxane units, and both ends of the molecular chain are blocked with triorganosiloxy groups. The viscosity of the linear organopolysiloxane is preferably 10 to 1000000 mPa·s, and more preferably 100 to 100000 mPa·s at 25° C.

Each of the alkenyl groups may be bonded to any part of the molecule. For example, the alkenyl group may be bonded to either a silicon atom that is at the end of the molecular chain or a silicon atom that is not at the end (but in the middle) of the molecular chain. In particular, a linear organopolysiloxane expressed by the following general formula (chemical formula 2) is preferred. The linear organopolysiloxane has 1 to 3 alkenyl groups on each of the silicon atoms at both ends of the molecular chain. In this case, however, if the total number of the alkenyl groups bonded to the silicon atoms at both ends of the molecular chain is less than 3, at least one alkenyl group is bonded to the silicon atom that is not at the end of (but in the middle of) the molecular chain (e.g., as a substituent in the diorganosiloxane unit). As described above, the viscosity of the linear organopolysiloxane is preferably 10 to 1000000 mPa·s at 25° C. in terms of workability and curability. Moreover, the linear organopolysiloxane may include a small amount of branched structure (trifunctional siloxane units) in the molecular chain.

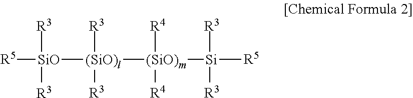

In this formula, R³ represents substituted or unsubstituted monovalent hydrocarbon groups that are the same as or different from each other, and at least one of them is an alkenyl group, R⁴ represents substituted or unsubstituted monovalent hydrocarbon groups that are the same as or different from each other and have no aliphatic unsaturated bond, R⁵ represents alkenyl groups, and 1 and m represent 0 or a positive integer. The monovalent hydrocarbon groups represented by R³ preferably have 1 to 10 carbon atoms, and more preferably 1 to 6 carbon atoms. Specific examples of the monovalent hydrocarbon groups include the following: alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; alkenyl groups such as vinyl, allyl, propenyl, isopropenyl, butenyl, hexenyl, cyclohexenyl, and octenyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups.

The monovalent hydrocarbon groups represented by R⁴ also preferably have 1 to 10 carbon atoms, and more preferably 1 to 6 carbon atoms. The monovalent hydrocarbon groups may be the same as the specific examples of R¹, but do not include an alkenyl group. The alkenyl groups represented by R⁵ preferably have 2 to 6 carbon atoms, and more preferably 2 to 3 carbon atoms. Specific examples of the alkenyl groups are the same as those of R² in the above formula (chemical formula 1), and the vinyl group is preferred.

In the general formula (chemical formula 2), 1 and m are typically 0 or positive integers satisfying 0<1+m≦10000, preferably 5≦1+m≦2000, and more preferably 10≦1+m 23 1200. Moreover; 1 and m are integers satisfying 0<1/(1+m)≦0.2, and preferably 0.0011≦1/(1+m)≦0.1.

(2) Crosslinking Component (Component (B))

The component (B) is an organohydrogenpolysiloxane that acts as a crosslinking agent. The addition reaction (hydrosilylation) between SiH groups in the component (3) and alkenyl groups in the component (A) produces a cured product. Any organohydrogenpolysiloxane that has two or more hydrogen atoms (i.e., SiH groups) bonded to silicon atoms per molecule may be used. The molecular structure of the organohydrogenpolysiloxane may be a linear, ring, branched, or three-dimensional network structure. The number of silicon atoms in a molecule (i.e., the degree of polymerization) may be 2 to 1000, and preferably about 2 to 300.

The locations of the silicon atoms to which the hydrogen atoms are bonded are not particularly limited. The silicon atoms may be either at the ends or not at the ends (but in the middle) of the molecular chain. The organic groups bonded to the silicon atoms other than the hydrogen atoms may be, e.g., substituted or unsubstituted monovalent hydrocarbon groups that have no aliphatic unsaturated bond, which are the same as those of R¹ in the above general formula (chemical formula 1).

The following structures can be given as examples of the organohydrogenpolysiloxane of the component (B).

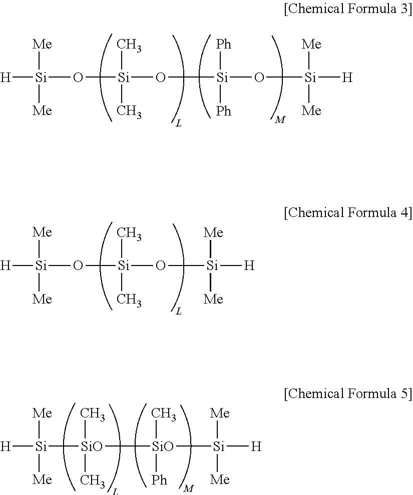

In these formulas, Ph represents organic groups including at least one of phenyl, epoxy, acryloyl, methacryloyl, and alkoxy groups, L is an integer of 0 to 1000, and preferably 0 to 300, and M is an integer of 1 to 200.

(3) Catalyst Component

The component (C) is a catalyst component that accelerates the curing of the composition of the present invention. The component (C) may be a known catalyst used for a hydrosilylation reaction. Examples of the catalyst include platinum group metal catalysts such as platinum-based, palladium-based, and rhodium-based catalysts. The platinum-based catalysts include, e.g., platinum black, platinum chloride, chloroplatinic acid, a reaction product of chloroplatinic acid and monohydric alcohol, a complex of chloroplatinic acid and olefin or vinylsiloxane, and platinum bisacetoacetate. The component (C) may be mixed in an amount that is required for curing, and the amount can be appropriately adjusted in accordance with the desired curing rate or the like. The component (C) is added at 0.01 to 1000 ppm based on the mass of metal atoms to the component (A).

(4) Heat Storage Inorganic Particles

As described above, the heat storage inorganic particles of the component (D) are composed of a material that undergoes an electronic phase transition and has a latent heat of 1 J/cc or more for the electronic phase transition. The heat storage inorganic particles are preferably metal oxide particles containing vanadium as the main metal component. The heat storage inorganic particles may be surface treated with a silane compound, a partial hydrolysate of the silane compound, or alkyl titanate. The silane compound is expressed by R(CH₃)ₐSi(OR′)₃₋ₐ, where R represents an alkyl group having 1 to 20 carbon atoms, R′ represents an alkyl group having 1 to 4 carbon atoms, and a is 0 or 1. If the heat storage inorganic particles are not surface treated, the curing of the polymer may be inhibited. Thus, the previous surface treatment of the heat storage inorganic particles can prevent the curing of the polymer from being inhibited.

(5) Heat Conductive Particles

If the heat conductive particles of the component (E) are added, the amount of the heat conductive particles is 100 to 2000 parts by mass with respect to 100 parts by mass of the matrix component. The addition of the heat conductive particles can further improve the heat conductivity of the heat storage composition. The heat conductive particles are preferably composed of at least one selected from alumina, zinc oxide, magnesium oxide, aluminum nitride, boron nitride, aluminum hydroxide, and silica. The heat conductive particles may have various shapes such as spherical, scaly, and polyhedral. When alumina is used, α-alumina with a purity of 99.5 mass % or more is preferred. The specific surface area of the heat conductive particles is preferably 0.06 to 10 m²/g. The specific surface area is a BET specific surface area, and is measured in accordance with JIS R1626. The average particle size of the heat conductive particles is preferably 0.1 to 100 μm. The particle size may be measured with a laser diffraction scattering method to determine a particle size at 50% (by mass). The method may use a laser diffraction particle size analyzer LA-950S2 manufactured by Horiba, Ltd.

The heat conductive particles preferably include at least two types of inorganic particles with different average particle sizes. This is because small-size inorganic particles fill the spaces between large-size inorganic particles, which can provide nearly the closest packing and improve the heat conductivity.

It is preferable that the inorganic particles are surface treated with a silane compound or its partial hydrolysate. The silane compound is expressed by R(CH₃)ₐSi(OR′)₃₋ₐ, where R represents an alkyl group having 1 to 20 carbon atoms, R′ represents an alkyl group having 1 to 4 carbon atoms, and a is 0 or 1. Examples of an alkoxysilane compound (simply refined to as “silane” in the following) expressed by R(CH₃)ₐSi(OR′)₃₋ₐ, where R represents an alkyl group having 1 to 20 carbon atoms, R′ represents an alkyl group having 1 to 4 carbon atoms, and a is 0 or 1, include the following: methyltrimethoxysilane; ethyltrimethoxysilane; propyltrimethoxysilane; butyltrimethoxysilane; pentyltrimethoxysilane; hexyltrimethoxysilane; hexyltriethmysilane; octyltrimethoxysilane; octyltriethoxysilane; decyltrimethoxysilane; decyltriethoxysilane; dodecyltrimethoxysilane; dodecyltriethoxysilane; hexadodecyltrimethoxysilane; hexadodecyltriethoxysilane; octadecyltrimethoxysilane; and octadecyltriethoxysilane. These silane compounds may be used individually or in combinations of two or more. The alkoxysilane and one-end silanol siloxane may be used together as the surface treatment agent. In this case, the surface treatment may include adsorption in addition to a covalent bond. It is preferable that the particles with an average particle size of 2 μm or more are added in an amount of 50 mass % or more when the total amount of particles is 100 mass %.

(6) Other Components

The composition of the present invention may include components other than the above as needed. For example, the composition may include an inorganic pigment such as colcothar, and alkoxy group-containing silicone such as alkyltrialkoysilane used, e.g., for the surface treatment of a filler.

The heat conductivity of a heat conductive silicone material of the present invention is 0.3 W/m·K or more, preferably 0.3 to 10 W/m·K, and more preferably 1 to 10 W/m·K. By controlling the heat conductivity within these ranges, heat can be efficiently transferred from the heat generating member to the heat storage material. The measurement method for the heat storage properties will be described in Examples.

The following describes favorable graphite sheets as the heat diffusing material. Graphite sheets are produced, for example, by a method of graphitizing a polymeric film, or a method of pulverizing a natural graphite and/or an expanded graphite into powder and forming it into a sheet by rolling. The method of graphitizing a polymeric film has a characteristic of high heat conductivity in a horizontal direction. The method of pulverizing a natural graphite and/or an expanded graphite into powder and forming it into a sheet by rolling has a characteristic of low cost. Graphite sheets obtained by these production methods can be used in the present invention. Particularly, for an application of heat diffusion, since the graphite sheet only needs to have a certain level of heat conductivity, it is preferable to use a graphite sheet produced by the method of pulverizing a natural graphite and/or an expanded graphite into powder and forming it into a sheet by rolling. The graphite sheet preferably has a thickness of 10 to 500 μm. The graphite sheet preferably has a heat conductivity in a planar direction of 20 to 2000 W/m·K. A graphite sheet with a higher heat conductivity s more preferred.

The heat storage sheet preferably has a thickness of 0.3 mm to 3.0 mm. The heat storage and conduction sheet preferably has a total thickness of 0.31 mm to 3.5 mm. Within the above ranges, the heat storage and conduction sheet can be thin enough to be conveniently incorporated into a heat generating component such as a semiconductor.

The corona discharge treatment is a treatment of applying a high voltage and high frequency between electrodes to ionize gas present in a space between the electrodes, thereby generating reactive groups (active groups) such as an —OH group and a —COOH group on laminating surfaces. By this treatment, adhesion between the heat storage sheet and the heat diffusing material can be enhanced. The discharge amount of the corona discharge treatment is preferably 10 to 1000 W·min/m². Within this range, adhesion between the heat storage sheet and the heat diffusing material can be high, and corona discharge can be productive and stable. The corona discharge treatment may be performed using, for example, an AGF-012 (model) manufactured by Kasuga Electric Works, Ltd.

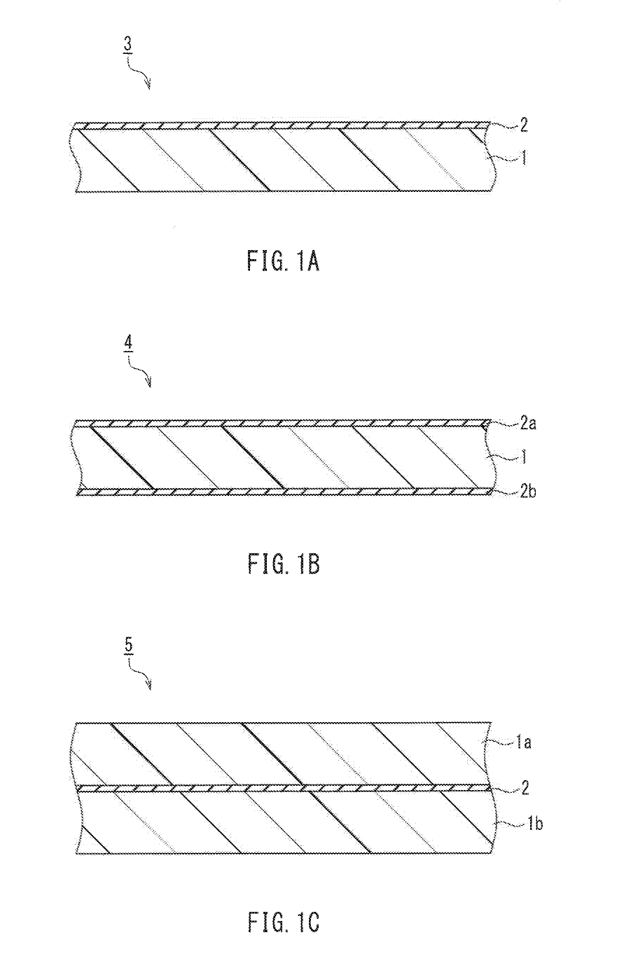

FIGS. 1A to 1C ,are schematic cross-sectional views of heat storage and conduction sheets in an example of the present invention. FIG. 1A shows an exemplary heat storage and conduction sheet 3 in which a heat diffusing material 2 is laminated on one principal surface of a heat storage sheet 1. FIG. 1B shows an exemplary heat storage and conduction sheet 4 in which heat diffusing materials 2a, 2b are laminated on both surfaces of a heat storage sheet 1. FIG. 1C shows an exemplary heat storage and conduction sheet 5 in which a heat diffusing material 2 is laminated in an inner layer of heat storage sheets 1a, 1b. The heat storage sheets 1, 1a, and 1b are obtained, for example, by adding heat storage inorganic particles and heat conductive particles to a silicone rubber (matrix resin), and forming the mixture into a sheet. The heat storage sheets 1, 1a, and 1b have high heat storage properties and high heat conduction properties. Laminating the heat diffusing material on the heat storage sheet can enhance heat diffusion properties in a planar direction. Each of the heat storage sheet 1 and the heat diffusing material 2 is layered and laminated.

### EXAMPLES

Hereinafter, the present invention will be described, by way of examples. However, the present invention is not limited to the following examples.

<Heat Diffusion Test>

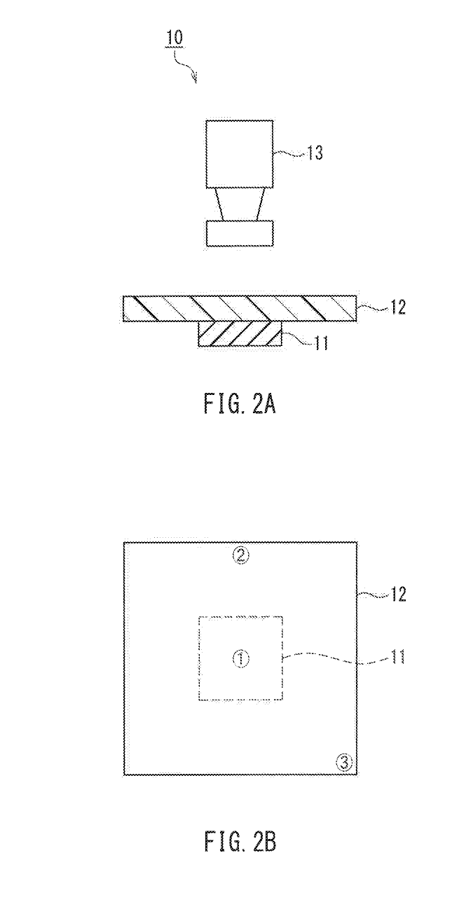

FIG. 2A shows a heat diffusion measuring apparatus 10. A heat storage and conduction sheet 12 was placed on a ceramic heater 11, and the temperature was measured by a thermograph 13 (manufactured by Apiste Corporation) that was located 150 mm above the heat storage and conduction sheet 12. The surface of the ceramic heater 11 was coated with grease, and the heat storage and conduction sheet 12 was attached to this surface so that contact heat resistance was reduced. The ceramic heater 11 as a heat source was 11 mm long and 9 mm wide, and was rated at 100 V, 100 W. The applied power was 5 W, and the temperature was 130° C. The heat storage and conduction sheet 12 was 50 mm long and 50 mm wide. FIG. 2B shows the measurement points of the heat storage and conduction sheet 12: the circled number 1 represents a central portion of the heat source; the circled number 2 represents an upper side of the heat source; and the circled number 3 represents a lower-right corner. The measurement was performed in an atmosphere at room temperature of 25° C. Regarding the thickness of the heat storage and conduction sheet 12, the heat storage and conduction silicone rubber sheet was 1.0 mm thick, and the graphite sheet was 0.1 mm thick. The measurement was performed in the following manner.
(1) In this test, infrared rays emitted from a test piece of a subject (the heat storage and conduction sheet 12) were analyzed. However, the energy amount varies depending on the emissivity of the subject even under the same temperature, and it is difficult to measure a material that reflects light. Therefore, a silicon-based carbon paint was coated on the surface of the test piece before measurement.
(2) The test piece (heat storage and conduction sheet 12) was set as shown in FIG. 2A, and the heat source was switched ON. The heat diffusion state was observed by image photography using the thermograph 13.
(3) Image photography was finished at a stage where the heat diffusion state reached an almost saturated state (about 3 minutes).
(4) After the image measurement, the change in temperature at points 1, 2 and 3 of FIG. 2B was measured.

<Method for Measuring Heat Resistance Value and Heat Conductivity>

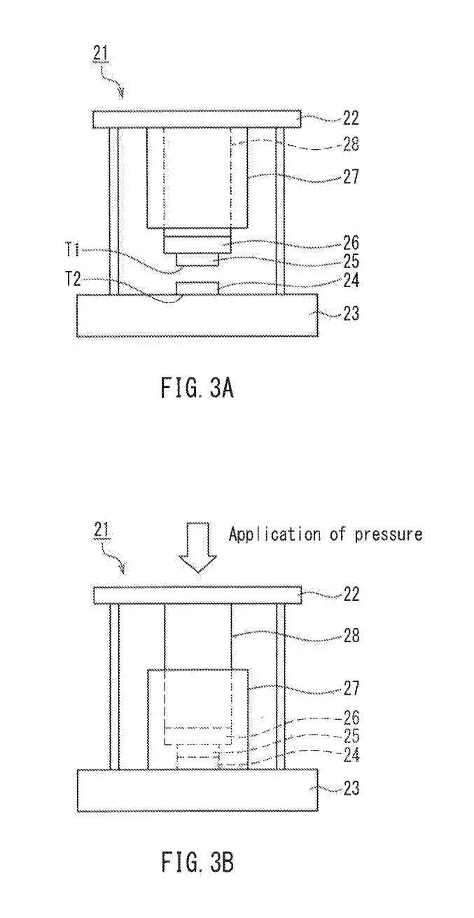

The measurement was performed using a TIM-Tester (manufactured by Analysis Tech Inc.) in accordance with ASTM D5470. FIGS. 3A to 3B show schematic views of a heat resistance measuring apparatus 21. As shown in FIG. 3A, a sheet sample 24 with a diameter of 33 mm is placed on a cooling plate 23. A heater 25, a load cell 26, and a cylinder 28 are incorporated in this order into the upper portion of the apparatus 21. A cylindrical heat insulator 27 is set outside of the cylinder 28 so as to move down. Reference numeral 22 represents a top. FIG. 3B shows the state of the apparatus 21 during the measurement. The cylinder 28 was driven to increase the pressure to 100 kPa. Based on a temperature difference between the temperature T1 of the heater 25 and the temperature T2 of the cooling plate 23 and a heat flow rate, a heat resistance value Rt was calculated by the following formula. The heat resistance value Rt and the thickness of the sample were used to calculate a heat conductivity

Rt=[(T1−T2)/Q]×S

Rt: Heat resistance value (° C.·cm²/W)

T1: Temperature of heater (° C.)

T2: Temperature of cooling plate (° C.)

Q: Heat flow rate (W)

S: Sample contact area (cm²)

<Specific Gravity>

The specific gravity was measured in accordance with JIS K 6220.

<Hardness>

The hardness was measured using a 3 mm thick sheet according to IRHD Supersoft. The measurement time was 10 seconds.

### Example 1

1. Material Component

(1) Silicone Component

Two-part, room temperature curing (two-part RTV) silicone rubber was used as a silicone component. A base polymer component (component (A)), a crosslinking component (component (B)), and a platinum-based metal catalyst (component (C)) had previously been added to the two-part RTV silicone rubber.

(2) Heat Storage Inorganic Particles

The particles of vanadium dioxide (VO₂) with an average particle size of 50 μm were added in an amount of 600 parts by mass (56 vol %) per 100 parts by mass of the silicone component, and uniformly mixed to obtain a compound. The latent heat of the vanadium dioxide (VO₂) particles produced during the electronic phase transition was 245 J/cc.

2. Sheet Forming and Processing Method

A 3 mm thick metal frame was placed on a polyester film that had been subjected to a release treatment. Subsequently, the compound was poured into the metal frame, on which another polyester film that had been subjected to a release treatment was disposed. This layered product was cured at a pressure of 5 MPa and a temperature of 120° C. for 10 minutes, thereby forming a heat storage silicone rubber sheet with a thickness of 1.0 mm. Table 1 shows the physical properties of the heat storage silicone rubber sheet thus formed.

Next, a 0.1 mm thick graphite sheet (heat diffusing material) was prepared. This graphite sheet had a heat conductivity in a planar direction of 700 W/m·K. The laminating surface of this graphite sheet and the laminating surface of the heat storage silicone rubber sheet obtained above (thickness 1.0 mm) were subjected to a corona discharge treatment. The corona discharge treatment was performed using an AGF-012 (model) manufactured by Kasuga Electric Works, Ltd. The discharge amount was 50W·min/m², and the treatment time was one minute. Thereafter, the heat storage silicone rubber sheet and the graphite sheet were laminated as shown in FIG. 1A. That is, they were laminated by direct bonding without using an adhesive.

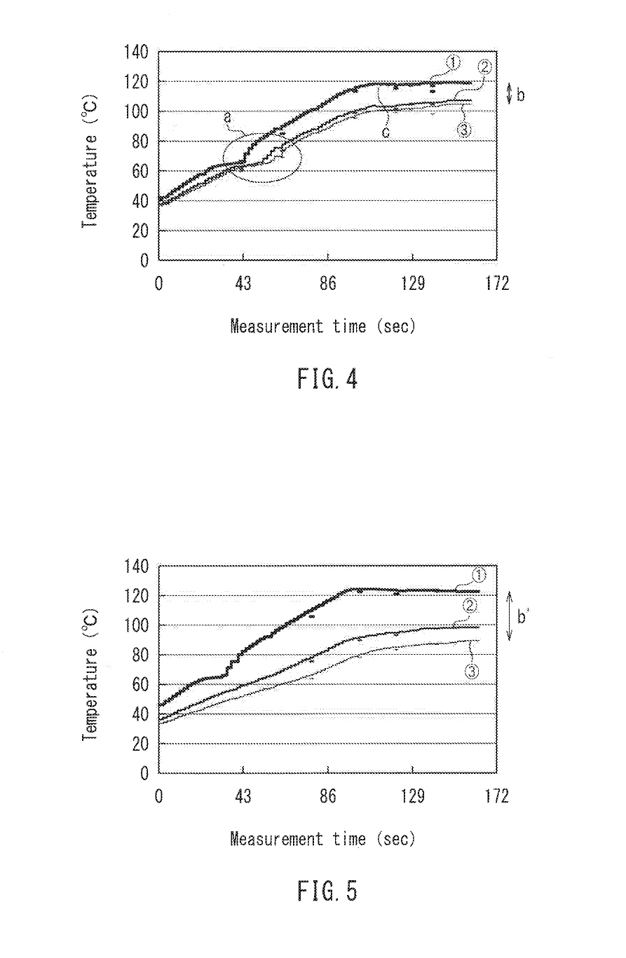

FIG. 4 is a graph showing the result of the heat storage test of the heat storage and conduction sheet in which the heat storage silicone rubber sheet and the graphite sheet are united. In FIG. 4, a line 1 represents the point 1 in FIG. 2B, a line 2 represents the point 2 in FIG. 2B, and a line 3 represents the point 3 in FIG. 2B. In an area a of FIG. 4, the heat storage effect was spread over the sheet. An arrow in an area b indicates that the variation in temperature in the sheet part was reduced, and heat was diffused favorably. In an area c, the temperature in the hot spot decreased, and heat was diffused favorably also in this area.

### Comparative Example 1

FIG. 5 is a graph showing the result of the heat storage test of the heat storage silicone rubber sheet alone before lamination with the graphite sheet of Example 1. In FIG. 5, a line 1 represents the point 1 in FIG. 2B, a line 2 represents the point 2 in FIG. 2B, and a line 3 represents the point 3 in FIG. 2B. An arrow in an area b′ of FIG. 5 indicates that the variation in temperature in the sheet part was larger than that in the area b of FIG. 4. In an area corresponding to the area a of FIG. 4, the heat storage effect was low over the sheet. In an area corresponding to the area c, the temperature in the hot spot was high. This indicates that the heat diffusion effect of FIG. 5 as a whole was lower than that of FIG. 4.

### Example 2

1. Material Component

(1) Silicone Component

Two-part, room temperature curing (two-part RTV) silicone rubber was used as a silicone component. A base polymer component (component (A)), a crosslinking component (component (B)), and a platinum-based metal catalyst (component (C)) had previously been added to the two-part RTV silicone rubber.

(2) Heat Storage Inorganic Particles

The particles of vanadium dioxide (VO₂) with an average particle size of 50 μm were added in an amount of 400 parts by mass (46 vol %) per 100 parts by mass of the silicone component, and uniformly mixed.

2. Sheet Forming and Processing Method

A sheet was formed in the same manner as in Example 1. Table 1 shows the physical properties of the heat storage silicone rubber sheet thus obtained.

TABLE 1

| | Ex. 1 | Ex. 2 |
|---|---|---|
| Silicone component (parts by | 100 | 100 |
| mass) | | |
| Amount of heat storage particles | VO₂: 600 | VO₂: 400 |
| added (parts by mass) | | |
| Heat storage properties (time | 60 | 55 |
| required for temperature rise | | |
| from 42° C. to 85° C.: sec) | | |
| Heat conductivity in thickness | 1.0 | 0.9 |
| direction (W/m · K) | | |
| Heat conductivity in planar | 700 | 700 |
| direction (W/m · K) | | |
| Specific gravity | 3.24 | 2.65 |
| Hardness (IRHD Supersoft) | 70.9 | 67.8 |

Next, a 0.1 mm thick graphite sheet was prepared. The laminating surface of the heat storage silicone rubber sheet obtained above (thickness 1.0 mm) and the laminating surface of the graphite sheet were laminated as shown in FIG. 1A. Since the filling amount of the filler was reduced, the heat storage silicone rubber sheet and the graphite sheet were made close contact with each other only by the surface tack force.

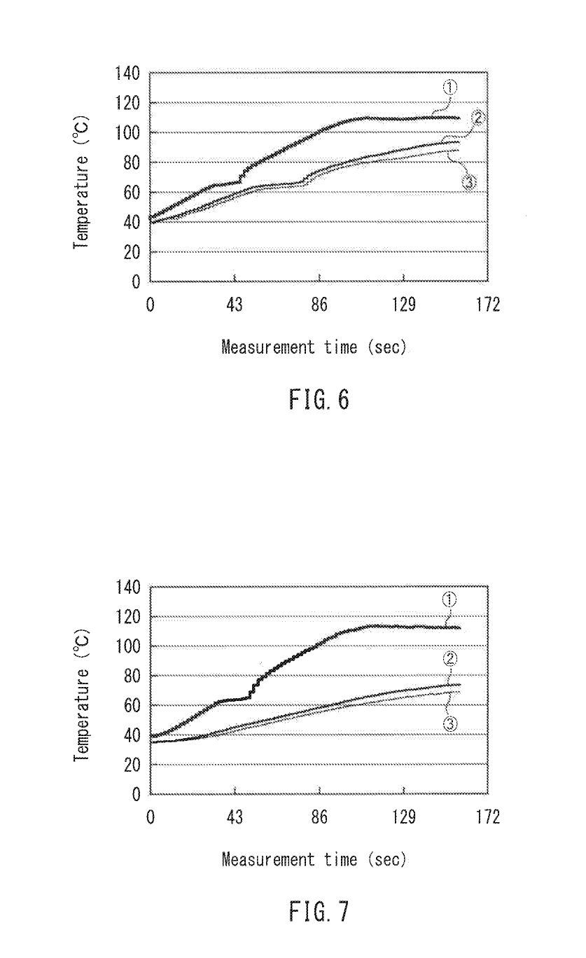

FIG. 6 is a graph showing the result of the heat storage test of the heat storage and conduction sheet in which the heat storage silicone rubber sheet and the graphite sheet are united. Since the amount of the heat storage material added was reduced as compared with Example 1, the heat storage effect was slightly reduced. However, a heat storage and conduction sheet thus obtained was adequate for practical use.

### Comparative Example 2

FIG. 7 is a graph showing the result of the heat storage test of the heat storage silicone rubber sheet alone before lamination with the graphite sheet of Example 2. FIG. 7 indicates that the heat storage effect and the heat diffusion effect of Comparative Example 2 (FIG. 7) were lower than those of Example 2 (FIG. 6).

### Example 3

This example exemplifies a composite of a silicone rubber sheet (thickness 1.0 mm) containing a heat storage material and a heat dissipating filler, and a graphite sheet (thickness 0.1 mm).

1. Material Component

(1) Silicone Component

Two-part, room temperature curing (two-part RTV) silicone rubber was used as a silicone component. A base polymer component (component (A)), a crosslinking component (component (B)), and a platinum-based metal catalyst (component (C)) had previously been added to the two-part RTV silicone rubber.

(2) Heat Storage Inorganic Particles

The particles of vanadium dioxide (VO₂) with an average particle size of 50 μm were added in an amount of 225 parts by mass (19 vol %) per 100 parts by mass of the silicone component, and uniformly mixed.

(3) Heat Conductive Filler

The particles of aluminium oxide (Al₂O₃) with an average particle size of 70 μm and 2 μm were added in an amount of 375 parts by mass (37 vol %) per 100 parts by mass of the silicone component, and uniformly mixed.

2. Sheet Forming and Processing Method

A sheet was formed in the same manner as in Example 1. Table 2 shows the physical properties of the heat storage silicone rubber sheet thus obtained.

3. Lamination with Heat Diffusing Material

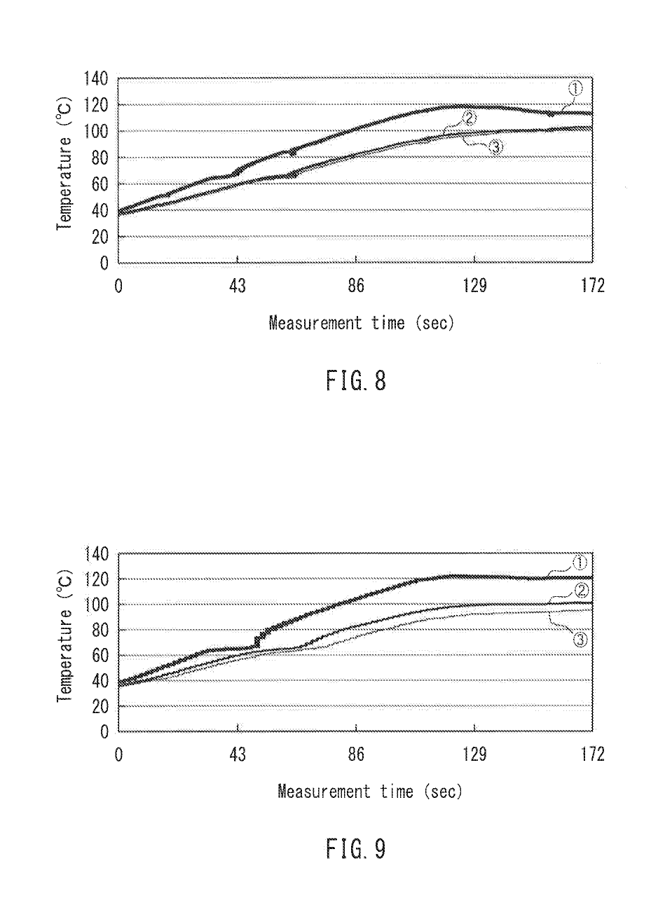

A 0.1 mm thick graphite sheet was prepared. The laminating surface of the heat storage silicone rubber sheet obtained above (thickness 1.0 mm) and the laminating surface of the graphite sheet were laminated in the same manner as in Example 1, as shown in FIG. 1A. FIG. 8 is a graph showing the result of the heat storage test of the laminated product.

### Example 4

This example exemplifies a silicone rubber sheet (thickness 1.0 mm) containing a heat storage material, and an aluminum sheet (thickness 0.04 mm).

1. Material Component

(1) Silicone Component

Two-part, room temperature curing (two-part RTV) silicone rubber was used as a silicone component. A base polymer component (component (A)), a crosslinking component (component (B)), and a platinum-based metal catalyst (component (C) had previously been added to the two-part RTV silicone rubber.

(2) Heat Storage Inorganic Particles

The particles of vanadium dioxide (VO₂) with an average particle size of 50 μm were added in an amount of 400 parts by mass (46 vol %) per 100 parts by mass of the silicone component, and uniformly mixed.

2. Sheet Forming and Processing Method

A sheet was formed in the same manner as in Example 1. Table 2 shows the physical properties of the heat storage silicone rubber sheet thus obtained.

3. Lamination with Heat Diffusing Material

A 0.04 mm thick aluminum sheet (heat conductivity in a planar direction: 270 W/m·K) was prepared. The laminating surface of the heat storage silicone rubber sheet obtained above (thickness 1.0 mm) and the laminating surface of the aluminum sheet were laminated in the same manner as in Example 1, as shown in FIG. 1A. FIG. 9 is a graph showing the result of the heat storage test of the laminated product.

### Example 5

This example exemplifies a silicone rubber sheet (thickness 1.0 mm) containing a heat storage material, and a copper sheet (thickness 0.035 mm).

1. Material Component

(1) Silicone Component

Two-part, room temperature curing (two-part RTV) silicone rubber was used as a silicone component. A base polymer component (component (A)), a crosslinking component (component (B)), and a platinum-based metal catalyst (component (C)) had previously been added to the two-part RTV silicone rubber.

(2) Heat Storage Inorganic Particles

The particles of vanadium dioxide (VO₂) with an average particle size of 50 μm were added in an amount of 400 parts by mass (46 vol %) per 100 parts by mass of the silicone component, and uniformly mixed.

2. Sheet Forming and Processing Method

A sheet was formed in the same manner as in Example 1. Table 2 shows the physical properties of the heat storage silicone rubber sheet thus obtained.

3. Lamination with Heat Diffusing Material

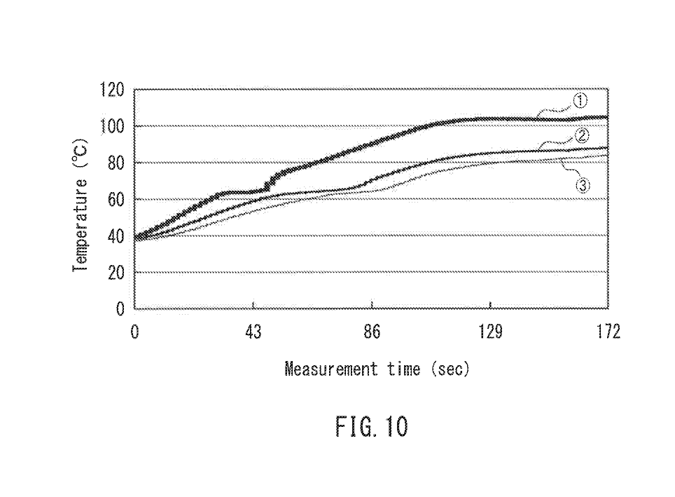

A 0.035 mm thick copper sheet was prepared. The laminating surface of the heat storage silicone rubber sheet obtained above (thickness 1.0 mm) and the laminating surface of the graphite sheet were laminated in the same manner as in Example 1, as shown in FIG. 1A. FIG. 10 is a graph showing the result of the heat storage test of the laminated product.

TABLE 2

| | Ex. 3 | Ex. 4 | Ex. 5 |
|---|---|---|---|
| Silicone component (parts by | 100 | 100 | 100 |
| mass) | | | |
| Amount of heat storage particles | VO₂: 225 | VO₂: 600 | VO₂: 600 |
| added (parts by mass) | | | |
| Amount of heat conductive | Al₂O₃: 375 | — | — |
| particles added (parts by mass) | | | |
| Heat storage properties (time | 58 | 55 | 70 |
| required for temperature rise | | | |
| from 42° C. to 85° C.: sec) | | | |
| Heat conductivity in thickness | 1.5 | 1.0 | 1.0 |
| direction (W/m · K) | | | |
| Heat condudictivity in planar | 700 | 230 | 380 |
| direction (W/m · K) | | | |
| Specific gravity | 2.80 | 3.24 | 3.24 |
| Hardness (IRHD Supersoft) | 94.0 | 70.9 | 70.9 |

As can be seen from Table 2 and FIGS. 8-40, the sheets of the Examples had high heat storage properties and high heat diffusion properties in a planar direction.

### INDUSTRIAL APPLICABILITY

The heat storage and conduction sheet of the present invention can be applied to products in various forms such as a sheet to be interposed between a heat generating member and a heat dissipating member of an electronic component.

### DESCRIPTION OF REFERENCE NUMERALS

1, 1a, 1b Heat storage sheet

2, 2a, 2b Heat diffusing material

3, 4, 5 Heat storage and conduction sheet

10 Heat diffusion measuring apparatus

11 Ceramic heater

12 Heat storage and conduction sheet

13 Thermograph

21 Heat resistance measuring apparatus

22 Top

23 Cooling plate

24 Sheet sample

25 Heater

26 Load cell

27 Heat insulator

28 Cylinder

1. A heat storage and conduction sheet, comprising:
a heat storage sheet comprising a matrix resin and heat storage inorganic particles; and
a heat diffusing material that is united with the heat storage sheet,
wherein the heat storage inorganic particles are composed of a material that undergoes an electronic phase transition and has a latent heat of 1 J/cc or more for the electronic phase transition, and an amount of the heat storage inorganic particles is 10 to 2000 parts by mass with respect to 100 parts by mass of the matrix resin,
the heat storage sheet has a heat conductivity of 0.3 W/m·K or more, and has a function of delaying heat conduction by storing heat so as to diffuse heat during the delay,
the heat diffusing material has a heat conductivity in a planar direction of 20 to 2000 W/m·K, and
a laminating surface of the heat storage sheet and a laminating surface of the heat diffusing material are laminated by direct bonding without using an adhesive.

2. The heat storage and conduction sheet according to claim 1, wherein the heat diffusing material is at least one selected from a graphite sheet, gold, platinum, silver, titanium, aluminum, palladium, copper, nickel, and alloys of these metals.

3. The heat storage and conduction sheet according to claim 1, wherein the heat storage inorganic particles are metal oxide particles containing vanadium as a main metal component.

4. The heat storage and conduction sheet according to claim 1, wherein the heat storage inorganic particles have an average particle size of 0.1 μm to 100 μm.

5. The heat storage and conduction sheet according to claim 1, wherein the matrix resin is at least one resin selected from a thermosetting resin and a thermoplastic resin.

6. The heat storage and conduction sheet according to claim 1, wherein the matrix resin is an organopolysiloxane.

7. The heat storage and conduction sheet according to claim 1, wherein the heat storage sheet further comprises 100 to 2000 parts by mass of heat conductive particles.

8. The heat storage and conduction sheet according to claim 7, wherein the heat conductive particles are surface treated with a silane compound or its partial hydrolysate, and the silane compound is expressed by R(CH₃)ₐSi(OR′)₃₋ₐ, where R represents an alkyl group having 1 to 20 carbon atoms, R′ represents an alkyl group having 1 to 4 carbon atoms, and a is 0 or 1.

9. (canceled)

10. The heat storage and conduction sheet according to claim 1, wherein the heat storage inorganic particles are surface treated with alkoxysilane or alkyl titanate.

11. (canceled)

12. The heat storage and conduction sheet according to claim 1, wherein the heat storage sheet has a thickness of 0.3 mm to 3.0 mm.

13. The heat storage and conduction sheet according to claim 1, wherein the heat storage and conduction sheet has a total thickness of 0.31 mm to 3.5 mm.
